(19) United States
(12) Patent Application Publication
(10) Pub. No.: US 2026/0247654 A1
(43) Pub. Date: Aug. 20, 2026

(54) POWER SEMICONDUCTOR DEVICE AND METHOD FOR FABRICATING THE SAME

(71) Applicant: HYUNDAI MOBIS CO., LTD., Seoul (KR)

(72) Inventor: Tae Yeop KIM, Yongin-si (KR)

(73) Assignee: HYUNDAI MOBIS CO., LTD., Seoul (KR)

(21) Appl. No.: 19/057,003

(22) Filed: Feb. 19, 2025

(51) Int. Cl. H10D 30/65; H10D 30/01; H10D 62/10; H10D 64/68; H10P 30/22

(52) U.S. Cl. CPC H10D 30/65; H10D 30/0285; H10D 62/125; H10D 64/68; H10P 30/22

(57) ABSTRACT

Provided are a power semiconductor device and a method for fabricating the same. The power semiconductor device includes an epitaxial layer having a first conductive type, a first and a second well regions having a second conductive type, and spaced apart from each other while making contact with the epitaxial layer, a first doping region having the second conductive type, and disposed at an upper portion of the epitaxial layer, between the first and the second well regions, a second doping region having the first conductive type, and disposed between the first well region and one side of the first doping region, and a third doping region having the first conductive type, and disposed between the second well region and an opposite side of the first doping region.

### BACKGROUND

### 1. Field

The present disclosure relates to a semiconductor device, and more particularly relates to a technology about a power semiconductor device for switching power transmitted and a method for fabricating the same.

### 2. Description of the Related Art

A power semiconductor device is a semiconductor device which operates under an environment of a higher voltage and a higher current. Such a power semiconductor device has been used in a field, such as an inverter device, necessary for switching high power. The power semiconductor device may include an insulated gate bipolar transistor (IGBT) or a power MOSFET. Such a power semiconductor device basically requires a withstanding voltage characteristic against a high voltage. Recently, additionally, the power semiconductor device requires a high-speed switching operation.

The semiconductor device operates, as electrons injected into a channel and a hole carrier injected into a collector flow. A power semiconductor device in a planar type may be easy to implement a process, as compared to a trench MOSFET, and may reduce an on-resistance by reducing a cell pitch.

However, in general, according to the power MOSFET in the planar type, channels may be irregular in length due to a mis-align phenomenon when being formed, thereby increasing a channel resistance.

### SUMMARY

The present disclosure has been made to solve the above-mentioned problems occurring in the prior art while advantages achieved by the prior art are maintained intact.

An aspect of the present disclosure provides a power semiconductor device, capable of preventing a mis-align phenomenon between left and right channels in a planar MOSFET power semiconductor, and a method for fabricating the same.

An aspect of the present disclosure provides a power semiconductor device, capable of reducing a channel resistance, and a method for fabricating the same.

Another aspect of the present disclosure provides a power semiconductor device, capable of ensuring robustness for the stress of an electric field, and a method for fabricating the same.

The technical problems to be solved by the present disclosure are not limited to the aforementioned problems, and any other technical problems not mentioned herein will be clearly understood from the following description by those skilled in the art to which the present disclosure pertains.

According to a general aspect of the present disclosure, a power semiconductor device may include an epitaxial layer including impurities in a first conductive type, a first well region and a second well region including impurities in a second conductive type different from the first conductive type, and disposed to be spaced apart from each other by a specific distance while making contact with the epitaxial layer, a first source region and a second source region including the impurities in the first conductive type, and disposed on top surfaces of the first well region and the second well region, respectively, a first doping region including the impurities in the second conductive type, and disposed at an upper portion of the epitaxial layer, between the first well region and the second well region, a second doping region including the impurities in the first conductive type, and interposed between the first well region and one surface of the first doping region while making contact with the first well region and the one surface of the first doping region , a third doping region including the impurities in the first conductive type, and interposed between the second well region and an opposite surface of the first doping region while making contact with the second well region and the opposite surface of the first doping region, and a gate overlapped with each of the first doping region, the second doping region, the third doping region, the source region, and the well region.

The second doping region and the third doping region may be formed at depths shallower than a depth at which the first doping region is formed.

The first doping region may be formed at a depth shallower than depths in which the first well region and the second well region, and the first source region and the second source region are formed.

The second doping region and the third doping region may have a doping concentration higher than a doping concentration of the epitaxial layer.

Each of a doping concentration of the first source region and the second source region may be higher than a doping concentration of the epitaxial layer, and a doping concentration of the second doping region and a doping concentration of the third doping region.

A doping concentration of the first doping region may be lower than a doping concentration of the first well region and a doping concentration of the second well region.

A thickness of opposite regions of the first doping region in the first direction may be thicker than a thickness of a center region of the first doping region.

The power semiconductor device may further include an insulating layer to separate the gate from a top surface of the epitaxial layer, and an electrode layer formed at an upper portion of the insulating layer and electrically connected to the first source region and the second source region.

The insulating layer may be configured to electrically insulate the gate from at least one of the well regions, the doping regions, or the source region, or electrically insulate the gate from the electrode layer, or a combination thereof.

The insulating layer may include Borophosphorsilicate Glass (BPSG).

According to another general aspect of the present disclosure, a method for fabricating a semiconductor device may include forming a first doping region, which includes the impurities in the first conductive type, on an entire surface of an upper portion of an epitaxial layer including the impurities in the first conductive type, forming a mask at a partial region of the upper portion of the epitaxial layer, forming a first spacer on opposite side surfaces of the mask such that at least a portion of the first spacer is overlapped with the first doping region, forming a first well region and a second well region including impurities in a second conductive type by employing the mask and the first spacer as a barrier layer, such that the first well region and the second well region are spaced apart from each other by a specific distance while making contact with the epitaxial layer, removing the first spacer and forming a second spacer on the opposite side surfaces of the mask, forming a first well region and a second well region including impurities in a second conductive type by employing the mask and the first spacer as a barrier layer, such that the first well region and the second well region are spaced apart from each other by a specific distance while making contact with the epitaxial layer, removing the second spacer, forming a second doping region under the mask by doping the impurities in the second conductive type, on opposite sidewalls of the mask, removing the mask, and forming a gate to be overlapped with each of the first doping region, the second doping region, the first source region, the second source region, the first well region, and the second well region.

The forming of the second spacer may include forming the second spacer having a width wider than a width of the first spacer in the first direction.

The forming of the second spacer may include forming the second spacer to be overlapped with each of the first doping region, the first well region, and the second well region.

The forming of the second spacer may include implanting impurity ions in the second conductive type to form a preset angle with respect to the epitaxial layer.

The method may further include forming an insulating layer to surround the gate, and forming an electrode layer at an upper portion of the insulating layer to be connected to the first source region and the second source region.

The first doping region may have a doping concentration higher than a doping concentration of the epitaxial layer.

A doping concentration of the first source region and a doping concentration of the second source region may be higher than a doping concentration of the epitaxial layer, and a doping concentration of the second doping region and a doping concentration of the third doping region.

A doping concentration of the second doping region may be lower than a doping concentration of the first well region and a doping concentration of the second well region.

The insulating layer may be configured to: electrically insulate the gate from at least one of the well regions, the doping regions, or the source region; or electrically insulate the gate from the electrode layer; or a combination thereof.

The insulating layer may include Borophosphorsilicate Glass (BPSG).

### BRIEF DESCRIPTION OF THE DRAWINGS

The above and other objects, features and advantages of the present disclosure will be more apparent from the following detailed description taken in conjunction with the accompanying drawings:

FIG. 1 is a cross-sectional view schematically illustrating a power semiconductor device, according to an embodiment of the present disclosure; and

FIGS. 2A to 2F are views schematically illustrating a method for fabricating a power semiconductor device, in a process sequence, according to an embodiment of the present disclosure.

### DETAILED DESCRIPTION

Hereinafter, various embodiments of the present disclosure will be described in detail with reference to accompanying drawings. In the present disclosure, the same components of the drawings will be assigned with the same reference numerals, and the redundant duplication of the same components will be omitted.

A description about a specific structure or a specific function in various embodiments of the present disclosure disclosed herein is provided only for the illustrative purpose of an embodiment of the present disclosure. Various embodiments of the present disclosure can be performed in various forms, and are not limited to embodiments described in the present disclosure.

The terms used herein are used only for specific embodiments, and the scope of another embodiment is not limited thereto. The terms of a singular form may include plural forms unless specified otherwise.

All terms used herein, including technical or scientific terms, have the same meanings as those generally understood by those skilled in the art to which the present disclosure pertains. Such terms, which are used herein, as those defined in a generally used dictionary are to be interpreted as having meanings equal to the contextual meanings in the related art, and are not to be interpreted as having ideal or excessively formal meanings unless defined clearly as having such in the present disclosure. Even if the terms are defined in the present disclosure, the terms should not be interpreted as excluding embodiments of the present disclosure if necessary.

In addition, in the following description of the present disclosure, a detailed description of well-known art or functions will be ruled out in order not to unnecessarily obscure the gist of the present disclosure.

Herein, a first conductive type and a second conductive type, which have mutually opposite conductive types, may have any one of an N-type and a P-type. For example, the first conductive type may be the N-type, and the second conductive type may be the P-type. In accompanying drawings, the above configuration of the conductive types is employed by way of example. However, the technical spirit of the present disclosure is not limited thereto. As another example, the first conductive type may be the P-type, and the second conductive type may be the N-type.

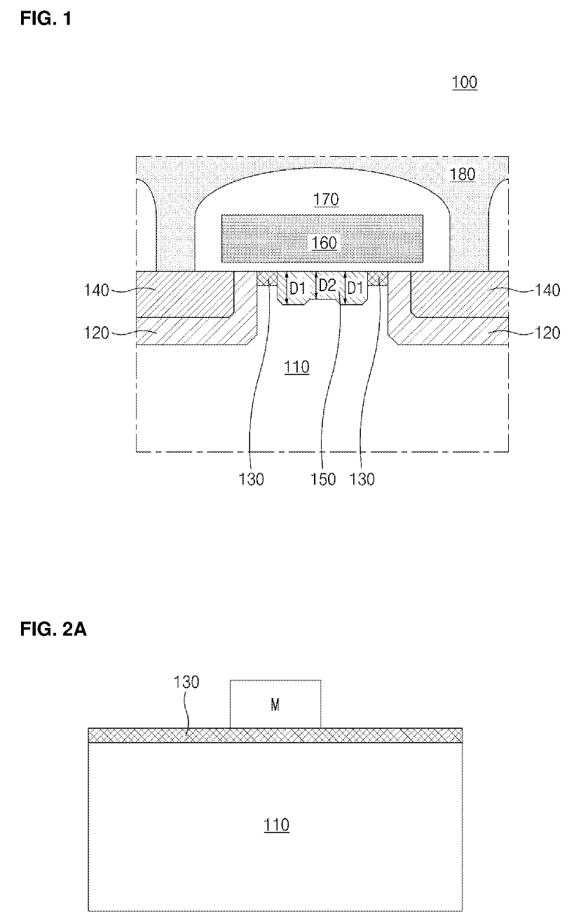

FIG. 1 is a cross-sectional view schematically illustrating a power semiconductor device according to an embodiment of the present disclosure. A cross-section of a power semiconductor device 100 having a planar Metal-Oxide-Semiconductor Field-Effect Transistor (MOSFET) structure is illustrated in FIG. 1.

Referring to FIG. 1, the power semiconductor device 100 may include an epitaxial layer 110 grown from a semiconductor substrate (not illustrated), a well region 120 extending from one surface of the epitaxial layer 110 to another surface of the epitaxial layer 110, a doping region 130 interposed between the well region 120 and a doping region 150 to make contact with the one surface of the epitaxial layer 110, a source region 140 disposed to have one surface and a bottom surface surrounded by the well region 120, the doping region 150 disposed to make contact with a side surface of the doping region 130 and the one surface of the epitaxial layer 110, and a gate 160 disposed to be overlapped with a partial region of the well region 120, a partial region of the source region 140, the doping region 130, and the doping region 150. In addition, the power semiconductor device 100 may further an electrode layer 180 separated from the gate 160 by an insulating layer 170.

The epitaxial layer 110 may have a first conductive type. The first conductive type may refer to an N-type conductive type by way of example. The epitaxial layer 110 may be formed by growing a thin film including N-type impurities from the semiconductor substrate (not illustrated). The epitaxial layer 110 may include an epitaxial layer including silicon carbide (SiC) including impurities (hereinafter, first conductive-type impurities) in the first conductive type.

Silicon carbide (SiC) may have a bandgap higher than a bandgap of silicon to maintain stability even at a higher temperature, as compared to silicon. Further, silicon carbide (SiC) exhibits an electric field for dielectric breakdown remarkably higher than that of silicon (Si). Accordingly, silicon carbide (SiC) may stably work even at a higher voltage. Accordingly, a power semiconductor device having the semiconductor layer including silicon carbide (SiC) may exhibit a more excellent heat dissipation characteristic with a higher breakdown voltage, and may exhibit a stable operating characteristic at a higher temperature, as compared to the case employing silicon (Si).

A plurality of well regions 120 may be formed on a surface layer part of the epitaxial layer 110 to be spaced apart from each other by a specific distance in a horizontal direction. The well region 120 may be formed to extend from the one surface of the epitaxial layer 110 toward the another surface of the epitaxial layer 110. The well region 120 may have a second conductive type. The second conductive type may refer to a P-type conductive type by way of example. The well region 120 may be formed through an ion implant process.

According to an embodiment, the mask may include a silicon oxide. As the mask is formed, a region in which the well region 120 is formed may be separated from a region in which the well region 120 is not formed.

The first conductive-type impurities are implanted into an entire surface of an upper portion of the epitaxial layer 110 to form the doping region 130. The doping region 130 may be formed at a constant depth. For example, the doping region 130 may have the depth shallower than depths of the well region 120, the source region 140, and the doping region 150. According to an embodiment, the doping region 130 may have a doping concentration higher than a doping concentration of the epitaxial layer 110.

The doping region 130 formed under the gate 160 may be divided into two doping regions by the doping region 150 disposed at the central region. The doping region 130 formed at a left side of the doping region 150 may be interposed between the well region 120 and one side surface of the doping region 150. In addition, the doping region 130 formed at a right side of the doping region 150 may be interposed between the well region 120 and an opposite side surface of the doping region 150.

The source region 140 may be formed by implanting the first conductive-type impurities into opposites sides of the upper portion of the epitaxial layer 110. The source region 140 may be formed in an internal surface layer part of the well region 120. The one side surface and the bottom surface of the source region 140 may be formed to be surrounded by the well region 120.

The source region 140 may have the first conductive type, and the doping concentration of the source region 140 may be higher than the doping concentration of the epitaxial layer 110 or the doping concentration of the doping region 130. The depth of the source region 140 may be deeper than depths of the doping region 130 and the depth of the doping region 150, and shallower than the depth of the well region 120. According to an embodiment, in the power semiconductor device 100, the source region 140 may act as a source of an MOSFET.

The doping region 130 having the doping concentration lower than the doping concentration of the source region 140 may be formed inside the power semiconductor device 100, thereby reducing a channel resistance. As the doping region 130 having the lower doping concentration is provided, electrons may easily move, when an active voltage is applied to the gate 160.

The doping region 150 may be formed in a space between the well regions 120 adjacent to each other. Opposite side surfaces of the doping region 150 may be formed to at least partially make contact with the doping region 130. In other words, doping regions 130 including the first conductive-type impurities may be formed under the gate 160, and the doping region 150 may be formed at a specific part between the doping regions 130 adjacent to each other. The doping region 150 may be doped with impurities (hereinafter, second conductive-type impurities) in the second conductive type the same as that of the well region 120.

The doping region 150 may be formed by implanting the second conductive-type impurities at a preset angle formed with respect to one surface of the epitaxial layer 110. To form the doping region 150, the second conductive-type impurities may be tilted at a preset angle with respect to a lower portion of a mask and implanted. In this case, the angle for implanting the impurity ions may be determined based on the number of times that atoms of the epitaxial layer 110 collide with the implanted impurities, and an implantation voltage.

In doping region 150, as the impurity ions are titled to have a preset angle and implanted from opposite side surfaces of a mask, the central region may have the form which is thinner than opposite regions. In other words, in the doping region 150, the thickness of the opposite regions, in which impurity ions are more heavily implanted, may be thicker than the central region in which impurity ions are more lightly implanted. For example, in the doping region 150, on the assumption that the thickness (depth) of the opposite regions is 'D1’, the central region may be formed with the thickness of ‘D2’ thinner (shallower) than ‘D1’. The form of the doping region 150 may be varied depending on the angle at which the above-described impurity ions are implanted.

The second conductive-type impurities are implanted into the opposite side surfaces of the mask to form the doping region 150, thereby preventing a punch through phenomenon. When an active voltage is applied to the gate of the power MOSFET, a channel region may be formed between the doping regions 130. In this case, as the doping region 130 is provided, a channel length may be reduced to prevent the punch through phenomenon.

In addition, when a channel length is asymmetrically formed in a transistor cell of a SiC power MOSFET, the difference of a current density is made for each transistor cell in switching on/off or conducting, and the ruggedness of the device may be weakened due to the thermal stress in an overcurrent conduction region in a transition state. In other words, when a surface electric field applied to the gate oxide layer is high, the robustness may be weakened due to the destruction of the oxide layer. Accordingly, according to an embodiment of the present invention, the field under the gate 160 may be protected by forming the doping region 150 to ensure robustness against electric field stress.

The gate 60 may be formed to be positioned at a specific portion of the insulating layer 170. As the insulating layer 170 may be formed at an upper portion, which traverses the well regions 120 adjacent to each other, of the semiconductor substrate, the gate 160 may be formed. In other words, the gate 160 may be disposed to be overlapped with the doping region 130, the doping region 150, the partial region of the source region 140, and the partial region of the well region 120.

The gate 160 may be separated from the one surface of the epitaxial layer 110 by the insulating layer 170. In other words, the gate 160 may be electrically insulated from the well region 120, the doping region 130, the source region 140, and the doping region 150 by the insulating layer 170. For example, the gate 160 may include polysilicon. According to another embodiment, the gate 160 may include a conductive material such as metal.

The insulating layer 170 may electrically insulate the gate 160 from the well region 120, the doping region 130, the source region 140, and the doping region 150, or may insulate the gate 160 from the electrode layer 180. According to an embodiment, the insulating layer 170 may include Borophosphorsilicate Glass (BPSG). The BPSG, which is a kind of a passivation layer allowing a low temperature process, may be strong against corrosion and make it easy to adjust a process parameter.

The electrode layer 180 may be formed to make contact with the source region 140 while being electrically connected to the source region 140. The electrode layer 180 may include a conductive material such as metal. According to an embodiment, the electrode layer 180 may act as a source electrode of the power semiconductor device 100. To bring the electrode layer 180 into contact with the source region 140, at least a portion, which is on the source region 140, of the insulating layer 170 may be removed.

Although not illustrated, the semiconductor substrate (not illustrated) may be provided under the epitaxial layer 110, and an additional conductive layer (not illustrated) may be further provided under the semiconductor substrate (not illustrated). According to an embodiment, the conductive layer (not illustrated) may act as a drain electrode of the power semiconductor device 100.

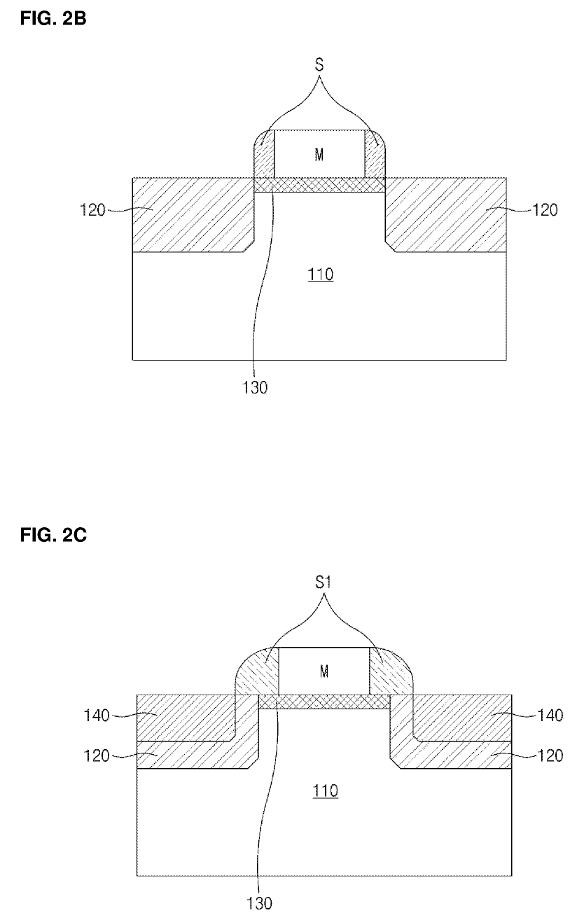

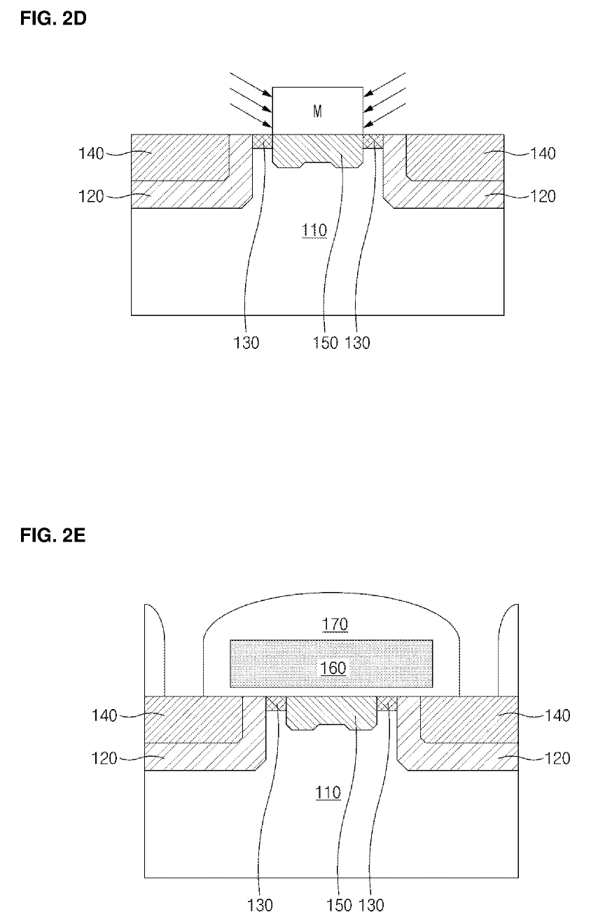

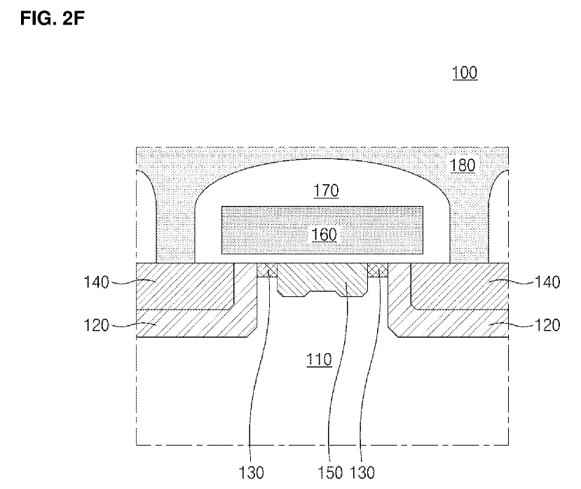

FIGS. 2A to 2F are views schematically illustrating a method for fabricating a power semiconductor device, in a process sequence, according to an embodiment of the present disclosure.

FIG. 2A illustrates a process for forming the doping region 130 on an entire surface of the upper portion of the epitaxial layer 110 provided on the semiconductor substrate (not illustrated).

The doping region 130 may be formed by ion-implanting the first conductive-type impurities from the one surface of the epitaxial layer 110 toward the another surface of the epitaxial layer 110. The doping region 130 may be formed to be thinner than the well region 120. As the first conductive-type impurities are ion-implanted, the depth at which the doping region 130 is formed may be uniformly maintained with respect to an entire portion of the power semiconductor device 100.

In addition, a mask M may be formed to be overlapped with a partial region on the epitaxial layer 110. In this case, the partial region on the epitaxial layer 110 may be the central region. According to an embodiment, the mask M may include a silicon oxide. As the mask M is formed, a region, in which the well region 120 is not formed, may be defined.

FIG. 2B illustrates a process for forming a first spacer S on opposite side surfaces of the mask M. For example, after conformally forming an insulating layer (not illustrated) for a spacer on the mask M and on a portion, which is exposed by the mask M, of the doping region 130, the insulating layer for the spacer may be anisotropically etched to expose a surface of the doping region 130, thereby forming the first spacer S on a sidewall of the mask M. The width of a region, in which the doping region 130 is formed, may be determined by the mask M and the first spacer S overlapped with an upper portion of the doping region 130.

The first spacer S may be overlapped with at least a portion of the doping region 130. The first spacer S may include a silicon nitride (Si3N4)

As the well region 120 is formed using the mask M and the first spacer S, a mis-align issue may be resolved. Such a manner may be referred to as a self-align manner.

The well regions 120 may be formed in the epitaxial layer 110 positioned at opposite sides of the first spacer S by using the mask M and the first spacer S as a barrier layer. The well region 120 may be formed by implanting the second conductive-type impurities into the one surface of epitaxial layer 110 toward the another surface of the epitaxial layer 110.

After forming the first spacer S, the well region 120 may be formed in the epitaxial layer 110 which is not overlapped with the mask M and the first spacer S.

The well region 120 may not be formed under the mask M and the first spacer S. In other words, only the doping region 130 may be formed under the mask M and the first spacer S.

FIG. 2C illustrates a process for forming the source region 140 using a second spacer S1 after removing the first spacer S. In other words, after the well region 120 is formed using the first spacer S as the barrier layer, the first spacer S is removed. In addition, the second spacer S1 may be formed at the opposite side surfaces of the mask M. The second spacer S1 may be overlapped with a top surface of the well region 120. In this case, the second spacer S1 may include a silicon nitride (Si3N4). The second spacer S1 may be formed to have a width wider than a width of the first spacer S in the horizontal direction.

The source region 140 may be formed by ion-implanting the first conductive-type impurities into the well regions 120 provided at opposite sides of the second spacer S1 by using the mask M and the second spacer S1 as the barrier layer. In other words, the source region 140 may be formed by implanting the first conductive-type impurities into the epitaxial layer 110 while ranging from the one surface of the epitaxial layer 110 toward the another surface of the epitaxial layer 110.

According to an embodiment, in the epitaxial layer 110, the depth at which the source region 140 is formed may be deeper than a depth at which the doping region 130 is formed. In addition, the doping concentration of the source region 140 may be higher than the doping concentration of the doping region 13.

As the power semiconductor device has the doping region 130 having the doping concentration lower than a doping concentration of the source region 140, electrons may easily move when the active voltage is applied to the gate 160. In other words, the channel resistance of the power semiconductor device may be reduced.

FIG. 2D illustrates a process for forming the doping region 150. After removing the second spacer S1, the second conductive-type impurities are implanted into opposite sidewalls of the mask M, thereby forming the doping region 150.

In this case, the second conductive-type impurities may be implanted while being tilted to form a preset angle with respect to the epitaxial layer 110. Accordingly, the doping region 150 may be formed under the mask M. At least a portion of the opposite side surfaces of the doping region 150 may make contact with the side surfaces of the doping region 130, and the doping concentration of the well region 120 may be higher than the doping concentration of the doping region 150.

As ions (for example, Po ions) may be implanted into the opposite sidewalls of the mask M to form the doping region 150, the mis-align may be prevented from being made due to the difference between left and right channel lengths of the power semiconductor device. In this case, as the doping region 150 is formed between the doping regions 130 adjacent to each other, the punch through phenomenon may be prevented. As the doping region 150 is formed through the process for forming the mask M and implanting the ions, thereby simplifying the fabricating process of the power semiconductor device and uniformly making the left and right shapes of the power semiconductor device. In addition, the doping region 150 is formed between the doping regions 130 to protect a field under the gate 160, thereby ensuring the robustness.

FIG. 2E illustrates a process for removing the mask M and forming the gate 160 and the insulating layer 170 on the epitaxial layer 110. In this case, the gate 160 may correspond to a gate electrode of the MOSFET. The insulating layer 170 may be formed to physically separate the one surface of the epitaxial layer 110 from the gate 160. In addition, the insulating layer 170 may be formed to surround four surfaces of the gate 160. According to an embodiment, the process may be configured to grow the remaining portion of the insulating layer 170, after the portion of the insulating layer 170 is grown and the gate 160 is formed.

For example, the gate 160 may include a conductive material such as polysilicon or metal, and the insulating layer 170 may include a passivation layer such as BPSG. For example, BPSG may be formed through a chemical vapor deposition process (CVD).

FIG. 2F illustrates a process for forming the electrode layer 180 on the insulating layer 170. The electrode layer 180 may make contact with the source region 140. To bring the electrode layer 180 into contact with the source region 140, a portion, which is overlapped with the source region 140, of the insulating layer 170 may be etched.

According to an embodiment of the present disclosure, the mis-align phenomenon between left and right channels may be prevented in the planar MOSFET power semiconductor.

According to an embodiment of the present disclosure, the channel resistance may be reduced.

According to an embodiment of the present disclosure, the ruggedness for the electric field stress may be ensured.

In addition, an embodiment of the present disclosure is provided only for the illustrative purpose. Those skilled in the art can make modification, variation, substitution, and addition of the embodiment within the technical spirit and the scope of the following claims, and it should be understood that the modification and the variation belong to the following claims.

Those skilled in the art can reproduce the present disclosure in the form of another embodiment, without changing the technical spirit or the essential features of the present disclosure. Accordingly, it should be understood that the embodiments described above are provided for the illustrative purpose, and the present disclosure is not limited thereto. The scope of the present disclosure falls into the scope of the appended claims instead of the detailed description, those skilled in the art should interpret that all variations or modifications derived from the meaning and the range of claims, and equivalents of the claims are included in the scope of the present disclosure.

Hereinabove, although the present disclosure has been described with reference to exemplary embodiments and the accompanying drawings, the present disclosure is not limited thereto, but may be variously modified and altered by those skilled in the art to which the present disclosure pertains without departing from the spirit and scope of the present disclosure claimed in the following claims.

What is claimed is:

1. A power semiconductor device comprising:
an epitaxial layer including impurities in a first conductive type;
a first well region and a second well region including impurities in a second conductive type different from the first conductive type, and disposed to be spaced apart from each other by a predetermined distance while making contact with the epitaxial layer;
a first source region and a second source region including the impurities in the first conductive type, and disposed on top surfaces of the first well region and the second well region, respectively;
a first doping region including the impurities in the second conductive type, and disposed at an upper portion of the epitaxial layer, between the first well region and the second well region;
a second doping region including the impurities in the first conductive type, and disposed between the first well region and one side of the first doping region while being contact with the first well region and the one side of the first doping region;
a third doping region including the impurities in the first conductive type, and disposed between the second well region and an opposite side of the first doping region while being contact with the second well region and the opposite side of the first doping region; and
a gate overlapped with each of the first doping region, the second doping region, the third doping region, the source region, and the well region.

2. The power semiconductor device of claim 1, wherein the second doping region and the third doping region are formed at depths shallower than a depth at which the first doping region is formed.

3. The power semiconductor device of claim 1, wherein the first doping region is formed at a depth shallower than depths in which the first well region and the second well region, and the first source region and the second source region are formed.

4. The power semiconductor device of claim 1, wherein the second doping region and the third doping region have a doping concentration higher than a doping concentration of the epitaxial layer.

5. The power semiconductor device of claim 1, wherein each of a doping concentration of the first source region and the second source region is higher than a doping concentration of the epitaxial layer, and a doping concentration of the second doping region and a doping concentration of the third doping region.

6. The power semiconductor device of claim 1, wherein a doping concentration of the first doping region is lower than a doping concentration of the first well region and a doping concentration of the second well region.

7. The power semiconductor device of claim 1, wherein a thickness of opposite regions of the first doping region in the first direction is thicker than a thickness of a center region of the first doping region.

8. The power semiconductor device of claim 1, further comprising:
an insulating layer to separate the gate from a top surface of the epitaxial layer; and
an electrode layer formed at an upper portion of the insulating layer and electrically connected to the first source region and the second source region.

9. The power semiconductor device of claim 8, wherein the insulating layer is configured to:
electrically insulate the gate from at least one of the well regions, the doping regions, or the source region; or
electrically insulate the gate from the electrode layer; or
a combination thereof.

10. The power semiconductor device of claim 8, wherein the insulating layer includes Borophosphorsilicate Glass (BPSG).

11. A method for fabricating a semiconductor device, the method comprising:
forming a first doping region, which includes impurities in a first conductive type, on an entire surface of an upper portion of an epitaxial layer including the impurities in the first conductive type;
forming a mask at a partial region of the upper portion of the epitaxial layer;
forming a first spacer on opposite side surfaces of the mask such that at least a portion of the first spacer is overlapped with the first doping region;
forming a first well region and a second well region including impurities in a second conductive type by employing the mask and the first spacer as a barrier layer, such that the first well region and the second well region are spaced apart from each other by a predetermined distance while making contact with the epitaxial layer;
removing the first spacer and forming a second spacer on the opposite side surfaces of the mask;
forming a first well region and a second well region including impurities in a second conductive type by employing the mask and the first spacer as a barrier layer, such that the first well region and the second well region are spaced apart from each other by a predetermined distance while making contact with the epitaxial layer;
removing the second spacer;
forming a second doping region under the mask by doping the impurities in the second conductive type, on the opposite surfaces of the mask;
removing the mask; and
forming a gate to be overlapped with each of the first doping region, the second doping region, the first source region, the second source region, the first well region, and the second well region.

12. The method of claim 11, wherein the forming of the second spacer includes:
forming the second spacer having a width wider than a width of the first spacer in the first direction.

13. The method of claim 11, wherein the forming of the second spacer includes:
forming the second spacer to be overlapped with each of the first doping region, the first well region, and the second well region.

14. The method of claim 11, wherein the forming of the second spacer includes:
implanting impurity ions in the second conductive type to form a preset angle with respect to the epitaxial layer.

15. The method of claim 11, further comprising:
forming an insulating layer to surround the gate; and
forming an electrode layer at an upper portion of the insulating layer to be connected to the first source region and the second source region.

16. The method of claim 11, wherein the first doping region has a doping concentration higher than a doping concentration of the epitaxial layer.

17. The method of claim 11, wherein a doping concentration of the first source region and a doping concentration of the second source region are higher than a doping concentration of the epitaxial layer, and a doping concentration of the second doping region and a doping concentration of the third doping region.

18. The method of claim 11, wherein a doping concentration of the second doping region is lower than a doping concentration of the first well region and a doping concentration of the second well region.

19. The method of claim 14, wherein the insulating layer is configured to:
electrically insulate the gate from at least one of the well regions, the doping regions, or the source region; or
electrically insulate the gate from the electrode layer; or
a combination thereof.

20. The method of claim 14, wherein the insulating layer includes Borophosphorsilicate Glass (BPSG).
